(19) United States
(12) Patent Application Publication
(10) Pub. No.: US 2012/0318585 A1
(43) Pub. Date: Dec. 20, 2012

(54) Touch Panel and Method for Manufacturing the Same

(75) Inventors: Jae Hun Kim, Seoul (KR); Seul Gi Kim, Gyunggi-do (KR); Sang Su Hong, Gyunggi-do (KR); Chung Mo Yang, Gyunggi-do (KR); In Hyung Lee, Gyunggi-do (KR); Woo Jin Lee, Seoul (KR); Young Woo Lee, Gyunggi-do (KR)

(73) Assignee: SAMSUNG ELECTRO-MECHANICS CO., LTD., Gyunggi-do (KR)

(21) Appl. No.: 13/223,185

(22) Filed: Aug. 31, 2011

(30) Foreign Application Priority Data
Jun. 14, 2011 (KR) 1020110057638

(51) Int. Cl. G06F 3/041; H05K 3/10

(52) U.S. Cl. 178/18.03; 29/846

(57) ABSTRACT

Disclosed herein are a touch panel and a method for manufacturing the same. The touch panel includes: a transparent substrate formed of silicon; and sensing electrodes each formed in a metal mesh pattern on one surface or both surfaces of the transparent substrate.

Since the transparent substrate is formed of silicon having excellent adhesive property, the sensing electrode can be formed on a transparent substrate even without a separate adhesive material.

### CROSS REFERENCE TO RELATED APPLICATION

This application claims the benefit of Korean Patent Application No. 10-2011-0057638, filed on Jun. 14, 2011, entitled “Touch Panel and Method for Manufacturing the Same”, which is hereby incorporated by reference in its entirety into this application.

### BACKGROUND OF THE INVENTION

1. Technical Field

The present invention relates to a touch panel and a method for manufacturing the same.

2. Description of the Related Art

As computers using digital techniques develop, computer assisted devices have also been developed together, and personal computers, portable transmission apparatus, other personal information processing apparatus, or the like perform text and graphic processes using various input devices, such as a keyboard or a mouse.

With the rapid advancement of an information-oriented society widening the use of computers more and more, the following problems come alight in that it being difficult to efficiently operate products using the keyboard and mouse as being currently responsible only for the input device function. Thus, the demand for a device that is simple, has minimum malfunction, and has the capability to easily input information is increasing.

Furthermore, current techniques for input devices exceed the level of fulfilling general functions and thus are progressing towards techniques related to high reliability, durability, innovation, designing and manufacturing. To this end, a touch panel has been developed as an input device capable of inputting information such as text and graphics.

The touch panel is mounted on the display surface of an image display device such as an electronic organizer, a flat panel display including a liquid crystal display (LCD) device, a plasma display panel (PDP), an electroluminescent (El), or the like, or a cathode ray tube (CRT), so that a user selects desired information while viewing the image display device.

The touch panel is classifiable as a resistive type, a capacitive type, an electromagnetic type, a surface acoustic wave (SAW) type, and an infrared type. The type of touch panel selected is one that is adapted for an electronic product in consideration of not only signal amplification problems, resolution differences, and the degree of difficulty of designing and manufacturing technology but also in light of optical characteristic, electrical properties, mechanical properties, resistance to the environment, input properties, durability, and economic benefits of the touch panel.

According to the touch panel of the prior art, a sensing electrode of recognizing touch is generally formed of indium tin oxide (ITO). However, ITO has problems in that a raw material thereof, that is, indium is a rare earth metal and thus expensive, as a result price competitiveness is undermined, and besides, it is expected to run out in 10 years, and as a result, supply thereof will not go far enough.

### SUMMARY OF THE INVENTION

The present invention has been made in an effort to provide a touch panel allowing the substitution of ITO by employing a metal mesh pattern as a sensing electrode and allowing the formation of the sensing electrode on a transparent substrate even without a separate adhesive layer by forming the transparent substrate of silicon having excellent adhesive property and flexibility, thereby improving flexibility of the transparent substrate, and a method for manufacturing the same.

According to a preferred embodiment of the present invention, there is provided a touch panel, including: a transparent substrate formed of silicon; and sensing electrodes each formed in a metal mesh pattern on one surface or both surfaces of the transparent substrate.

The silicon may be at least one selected from a group consisting of polydimethylsiloxane, polymethylhydrosiloxane, polymethylphenylsiloxane and polydiphenylsiloxane.

The transparent substrate formed of silicon may have an adhesive property.

The sensing electrode may be formed by patterning a copper foil in a mesh pattern.

A black oxide treatment may be performed on a surface of the sensing electrode.

Electrode wirings may be formed outside the sensing electrodes.

The sensing electrode and the electrode wiring may be formed in a single body.

According to another preferred embodiment of the present invention, there is provided a method for manufacturing a touch panel, including: (A) stacking a metal foil on one surface or both surfaces of a transparent substrate formed of silicon; and (B) selectively patterning the metal foil to form each of the sensing electrodes in a mesh pattern.

The silicon may be at least one selected from a group consisting of polydimethylsiloxane, polymethylhydrosiloxane, polymethylphenylsiloxane and polydiphenylsiloxane, in step (A).

The metal foil may be a copper foil, in step (A).

The method may further include performing a black oxide treatment on a surface of the copper foil before step (A).

The transparent substrate formed of silicon may have an adhesive property, in step (A).

The method may further include depositing an etching resist on the metal foil, before or after step (A). Here, Step (B) may include: (B1) patterning the etching resist to form openings; and (B2) selectively etching a portion of the metal foil, which is exposed through the openings of the etching resist, to form the sensing electrode in a mesh pattern.

The etching resist may be a dry film, and step (B1) may include: depositing an art work film above the dry film; exposing the dry film to selectively cure the dry film; and patterning the dry film by removing a portion except a cured portion of the dry film, to form openings in the dry film.

In the depositing of the etching resist on the metal foil, the etching resist may be a dry film, and a protecting layer may be provided on the other surface of the dry film when one surface of the dry film is contacted with the metal foil.

### BRIEF DESCRIPTION OF THE DRAWINGS

FIG. 1 is a cross-sectional view of a touch panel according to a preferred embodiment of the present invention;

FIG. 2 is a plane view of the touch panel manufactured according to the preferred embodiment of the present invention; and

FIGS. 3 to 10 are cross-sectional views showing a method of manufacturing a touch panel according to a preferred embodiment of the present invention in processing sequence.

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, in describing the present invention, a detailed description of related known functions or configurations will be omitted so as not to obscure the gist of the present invention.

Hereinafter, preferred embodiments of the present invention will be described in detail with reference to the accompanying drawings.

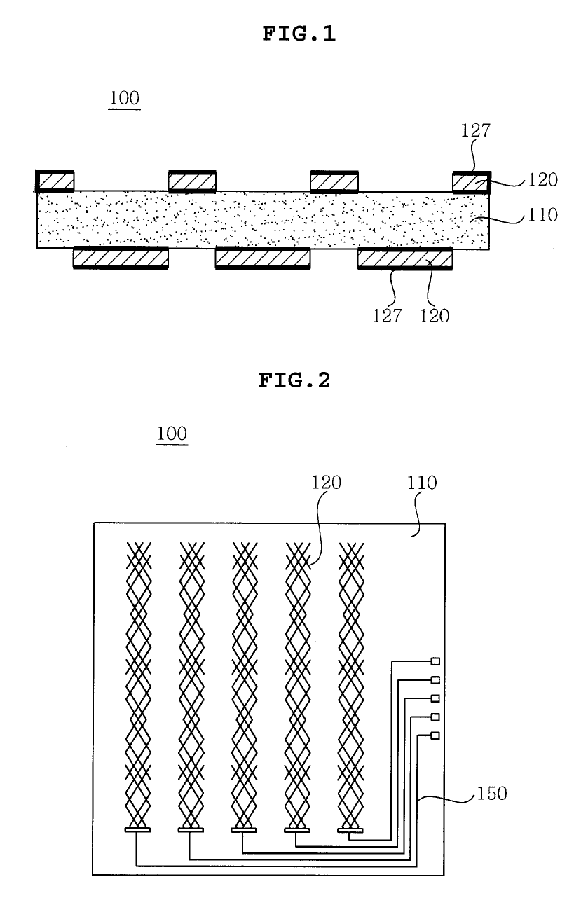

FIG. 1 is a cross-sectional view of a touch panel according to a preferred embodiment of the present invention, and FIG. 2 is a plane view of the touch panel according to the preferred embodiment of the present invention.

As shown in FIGS. 1 and 2, a touch panel 100 according to a preferred embodiment of the present invention includes a transparent substrate 110 formed of silicon, and sensing electrodes 120 formed of metal. The sensing electrodes are formed on one surface or both surfaces of the transparent substrate 110 in a mesh pattern.

The transparent substrate 110 serves to provide a region where the sensing electrodes 120 are to be formed. Here, the transparent substrate 110 is formed of silicon, and more specifically, the silicon is preferably at least one selected from a group consisting of polydimethylsiloxane, polymethylhydrosiloxane, polymethylphenylsiloxane, and polydiphenylsiloxane. As such, since the transparent substrate 110 is formed of silicon, the transparent substrate 110 has holding force with a predetermined strength or more, thereby stably holding the sensing electrodes 120, and has an adhesive force, thereby forming the sensing electrodes 120 directly on the transparent substrate 110 even without an additive adhesive material. Therefore, the manufacturing process of the touch panel 100 can be simplified and the manufacturing costs thereof can be reduced. However, the additive adhesive material does not need to be absolutely applied to the transparent substrate 110. In order to enhance an adhesive strength between the transparent substrate 110 and the sensing electrodes 120, a primer treatment may be performed on the transparent substrate 110. In addition, the transparent substrate 110 formed of silicon has excellent flexibility.

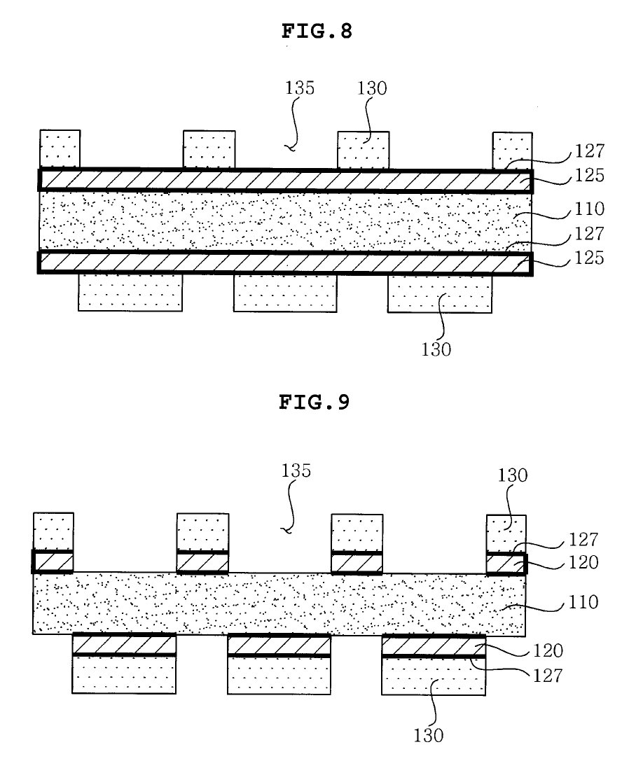

The sensing electrode 120 functions to generate signals at the time of touching an input unit and allow a controller to recognize touched coordinates, and is formed on the transparent substrate 110. Here, the sensing electrode 120 is formed of metal in a mesh pattern. Here, a metal component for forming the sensing electrode 120 is preferably copper (Cu), aluminum (Al), gold (Au), silver (Ag), titanium (Ti), palladium (Pd), chrome (Cr), or a combination thereof, but is not limited thereto. Also, the sensing electrode 120 may be formed by patterning a metal foil in a mesh pattern (see FIGS. 8 and 9), and a copper foil is preferably used as the metal foil. A process of patterning the metal foil in a mesh pattern will be specifically described in a manufacturing method of the touch panel 100. As described above, since the touch panel 100 according to the present preferred embodiment has the sensing electrode 120 formed in a metal mesh pattern, it can secure price competitiveness as compared with the prior art where the sensing electrode 120 is formed of high-price ITO.

The sensing electrodes 120 are formed on both surfaces of the transparent substrate 110 in the drawing (see FIG. 1), but the right scope of the present invention is not limited thereto. The sensing electrodes 120 may also be formed on only one surface of the transparent substrate 110.

Meanwhile, in a case where the sensing electrode 120 is formed by patterning a copper foil in a mesh pattern, a black oxide treatment is preferably performed on a surface of the sensing electrode 120.

Meanwhile, in a case where the sensing electrode 120 is formed by patterning a copper foil in a mesh pattern, a black oxide treatment is preferably performed on a surface of the sensing electrode 120 to form a blackened surface 127. Here, the black oxide treatment means that the surface of the sensing electrode (copper foil) 120 is oxidized to precipitate Cu₂O or CuO. Cu₂O is called brown oxide because it exhibits brown color, and CuO is called black oxide because it exhibits black color. As such, a black oxide treatment is performed on the surface of the sensing electrode 120, thereby preventing light from being reflected onto the sensing electrode 120, and as the result, visibility of the touch panel 100 can be improved.

Also, as shown in FIG. 2, electrode wirings 150 are formed outside the sensing electrodes 120, to receive electric signals from the sensing electrodes 120. Here, the electrode wirings 150 may be formed by using the same component as the sensing electrodes 120. Here, the sensing electrode 120 and the electrode wiring 150 are formed in a single body. That is, when patterning the metal foil, the sensing electrodes 120 are formed, and at the same time, the electrode wirings 150 are formed. However, this is only the example, and the electrode wirings 150 may be printed, independently of the sensing electrodes 120, by using screen printing, gravure printing, inkjet printing, or the like. Here, as a material of the electrode wiring 150, a material consisting of silver (Ag) paste or organic silver, which has excellent electric conductivity, as well as a conductive polymer, carbon black (including CNT), or a low-resistive metal including metal oxide such as ITO or metals. Meanwhile, the electrode wiring 150 is connected to only one end of the sensing electrode 120 in the drawing, but this is not only example. For example, the electrode wiring 150 is connected to both ends of the sensing electrode 120 according to the type of the touch panel 100.

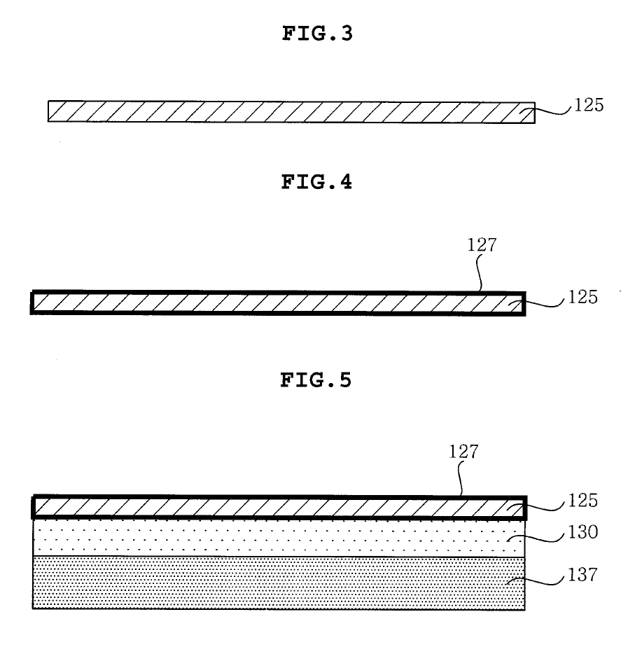

FIGS. 3 to 10 are cross-sectional views showing a method of manufacturing a touch panel according to a preferred embodiment of the present invention in processing sequence.

As shown in FIGS. 3 to 10, a method for manufacturing a touch panel 100 according to a preferred embodiment of the present invention includes: (A) stacking a metal foil 125 on one surface or both surfaces of a transparent substrate 110 formed of silicon; and (B) selectively patterning the metal foil 125 to form each of sensing electrodes 120 in a mesh pattern.

First, as shown in FIG. 3, a metal foil 125 is prepared. Here, the metal foil 125 is preferably a copper foil, but is not limited thereto. A component of the metal foil 125 may be aluminum (Al), gold (Au), silver (Ag), titanium (Ti), palladium (Pd), chrome (Cr), or a combination thereof.

Next, as shown in FIG. 4, if the metal foil 125 is a copper foil, a black oxide treatment is performed on a surface of the copper foil 125 Here, the black oxide treatment is performed by heat-treating the copper foil 125 at a temperature of 100□ or higher to oxidize the surface of the copper foil 125. As such, by performing the black oxide treatment on the surface of the copper foil 125, a blackened surface 127 remains on the surface of the sensing electrode 120 when the copper foil 125 is patterned to form the sensing electrode 120, thereby preventing light from being reflected from the sensing electrode 120.

Next, as shown FIG. 5, an etching resist 130 is deposited on the metal foil 125. Here, a dry film is preferably used as the etching resist 130, and hereinafter the etching resist 130 will be described by taking the dry film as an example. However, the etching resist 130 is not limited to the dry film, and all kinds of etching resists known to the art, such as, a liquid-state photosensitive material may also be used. In a case where the etching resist 130 is the dry film, a protecting layer 137 for holding the dry film 130 may be provided. In other words, when the metal foil 125 is contacted with one surface of the dry film 130, the protecting layer 137 is provided on the other surface of the dry film 130. Here, the protecting layer 137 may be formed of polyethyleneterephtalate (PET) or the like.

Meanwhile, the present step (depositing the etching resist 130 on the metal foil 125) may be performed after the next step (stacking the metal foil 125 on the transparent substrate 110), as necessary.

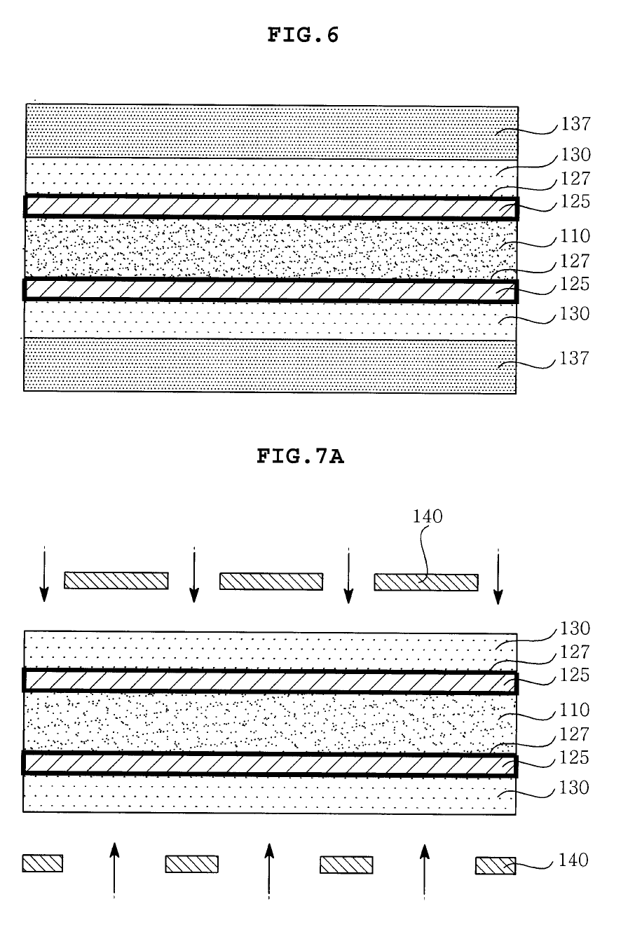

Next, as shown in FIG. 6, the metal foil 125 is stacked on the transparent substrate. Here, the transparent substrate 110 is formed of silicon, and the silicon is preferably at least one selected from a group consisting of polydimethylsiloxane, polymethylhydrosiloxane, polymethylphenylsiloxane, and polydiphenylsiloxane. Since the transparent substrate 110 formed of silicon has an adhesive property, the metal foil 125 can be stacked and fixed directly on the transparent substrate 110 even without an additive adhesive material. However, the additive adhesive material are absolutely needed, and a primary treatment is performed on the transparent substrate 110 in order to enhance an adhesive strength between the transparent substrate 110 and the metal foil 125 before the metal foil 125 is stacked. Meanwhile, the metal foil 125 is stacked on both surfaces of the transparent substrate 110 in drawings, but it may be stacked on only one surface of the transparent substrate 110, as necessary.

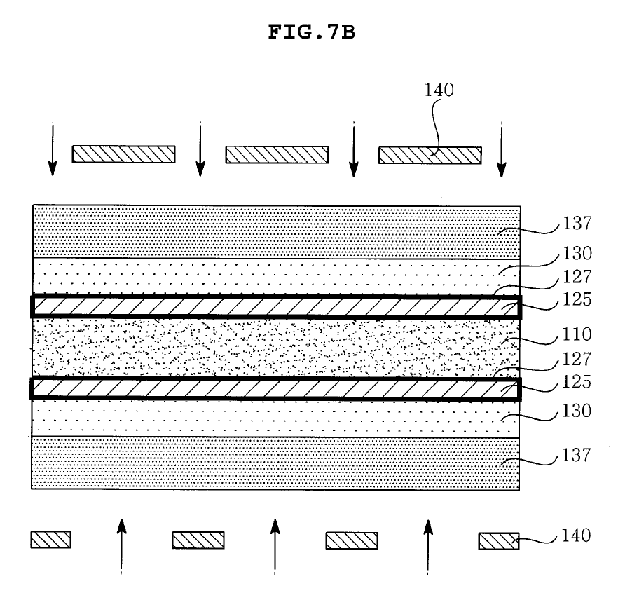

Next, as shown in FIGS. 7A and 7B, an artwork film 140 is disposed above the dry film 130, and then the dry film 130 is selectively cured through exposure. More specifically, the artwork film 140 is disposed above the dry film 130 and then the dry film 130 is exposed to ultraviolet light, and thereby, the dry film 130 is selectively cured. Here, both of the dry films 130 provided at both sides of the transparent substrate 110 may be exposed simultaneously or one by one.

Meanwhile, the dry film 130 may be exposed after the protecting layer 137 is removed from the dry film 130 as shown in FIG. 7A, but the dry film 130 may be exposed while the protecting layer 137 is not removed from the dry film 130 as shown in FIG. 7B. As such, when two dry films 130 are exposed one by one while the protecting layer 137 is not removed from the dry film 130, the protecting layer 137 can prevent scratch or contamination from being generated on the dry film 130.

Next, as shown in FIG. 8, the dry film 130 is patterned to form an opening 135 by removing a portion of the dry film 130 except a cured portion thereof. Since the dry film 130 is selectively cured in the previous step, a non-cured portion of the dry film 130 may be resolved and removed by using a developing solution of sodium carbonate (Na₂CO₃) or potassium carbonate (K₂CO₃) in the present step. As such, the dry film 130 may be selectively removed, thereby forming an opening 135.

Next, as shown in FIG. 9, a portion of the metal foil 125, which is exposed through the opening 135 of the dry film 130, is selectively etched and patterned, thereby forming a sensing electrode 120 having a mesh pattern. Here, if an etching solution is supplied through the opening 135 of the dry film, the exposed portion of the metal foil 125 through the dry film 130 can be selectively etched and patterned. As such, the metal foil 125 is selectively patterned, thereby forming the sensing electrode 120 having a mesh pattern. Here, an iron chloride (FeCl₃) etching solution, an copper (II) chloride (CuCl₂) etching solution, an alkaline etching solution, a hydrogen peroxide/sulfuric acid (H₂O₂/H₂SO₄)-based etching solution, or the like may be used when the metal foil 125 is etched.

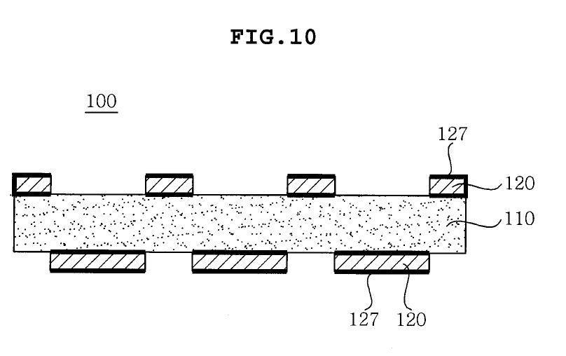

Next, as shown in FIG. 10, the dry film 130 is removed from the sensing electrodes 120. Since the function of the dry film 130 is finished when forming of the sensing electrode 120 is completed, the dry film 130 is removed by using a stripping solution. Here, the dry film 130 is stripped by using a stripping solution of NaOH or KOH. Specifically, the dry film 130 is peeled off during a combining procedure of a hydroxyl group (OH) in the stripping solution and a carboxyl group (COOH⁺) in the dry film 130, and then stripped from the sensing electrode 120.

As such, the dry film 130 is removed from the sensing electrodes 120, and thus, a touch panel 100 including a transparent substrate 110 formed of silicon and sensing electrodes 120 formed of a metal mesh pattern on the transparent substrate 110 can be completely manufactured.

According to the present invention, the sensing electrode is formed of metal to have a mesh pattern, which allows the substitution of high-priced ITO, thereby securing price competitiveness of the touch panel.

Furthermore, the black oxide treatment is finally performed on the metal foil for forming the sensing electrode, which prevents light from being reflected from the sensing electrode, thereby improving visibility of the touch panel.

Furthermore, the transparent substrate is formed of silicon having an excellent adhesive property, thereby forming the sensing electrode on the transparent substrate even without an additive adhesive material. Therefore, the manufacturing process of the touch panel can be simplified and the manufacturing costs thereof can be reduced. In addition, the transparent substrate formed of silicon has an advantage of excellent flexibility.

Although the preferred embodiments of the present invention have been disclosed for illustrative purposes, they are for specifically explaining the present invention and thus a touch panel and a method of manufacturing the same according to the present invention are not limited thereto, but those skilled in the art will appreciate that various modifications, additions and substitutions are possible, without departing from the scope and spirit of the invention as disclosed in the accompanying claims. Accordingly, any and all modifications, variations or equivalent arrangements should be considered to be within the scope of the invention, and the detailed scope of the invention will be disclosed by the accompanying claims.

What is claimed is:

1. A touch panel, comprising:
a transparent substrate formed of silicon; and
sensing electrodes each formed in a metal mesh pattern on one surface or both surfaces of the transparent substrate.

2. The touch panel as set forth in claim 1, wherein the silicon is at least one selected from a group consisting of polydimethylsiloxane, polymethylhydrosiloxane, polymethylphenylsiloxane and polydiphenylsiloxane.

3. The touch panel as set forth in claim 1, wherein the transparent substrate formed of silicon has an adhesive property.

4. The touch panel as set forth in claim 1, wherein the sensing electrode is formed by patterning a copper foil in a mesh pattern.

5. The touch panel as set forth in claim 4, wherein a black oxide treatment is performed on a surface of the sensing electrode.

6. The touch panel as set forth in claim 1, wherein electrode wirings are formed outside the sensing electrodes.

7. The touch panel as set forth in claim 6, wherein the sensing electrode and the electrode wiring are formed in a single body.

8. A method for manufacturing a touch panel, comprising:
(A) stacking a metal foil on one surface or both surfaces of a transparent substrate formed of silicon; and
(B) selectively patterning the metal foil to form each of the sensing electrodes in a mesh pattern.

9. The method as set forth in claim 8, wherein the silicon is at least one selected from a group consisting of polydimethylsiloxane, polymethylhydrosiloxane, polymethylphenylsiloxane and polydiphenylsiloxane, in step (A).

10. The method as set forth in claim 8, wherein the metal foil is a copper foil, in step (A).

11. The method as set forth in claim 10, further comprising performing a black oxide treatment on a surface of the copper foil before step (A).

12. The method as set forth in claim 8, wherein the transparent substrate formed of silicon has an adhesive property, in step (A).

13. The method as set forth in claim 8, further comprising depositing an etching resist on the metal foil, before or after step (A),
wherein step (B) includes: (B1) patterning the etching resist to form openings; and (B2) selectively etching a portion of the metal foil, which is exposed through the openings of the etching resist, to form the sensing electrode in a mesh pattern.

14. The method as set forth in claim 13, wherein the etching resist is a dry film, and step (B1) includes: depositing an art work film above the dry film; exposing the dry film to selectively cure the dry film; and patterning the dry film by removing a portion except a cured portion of the dry film, to form openings in the dry film.

15. The method as set forth in claim 13, wherein in the depositing of the etching resist on the metal foil, the etching resist is a dry film, and a protecting layer is provided on the other surface of the dry film when one surface of the dry film is contacted with the metal foil.
